(19) United States
(12) Patent Application Publication
(10) Pub. No.: US 2026/0255761 A1
(43) Pub. Date: Aug. 27, 2026

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventor: Bingkun YIN, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/860,609

(22) PCT Filed: Aug. 22, 2023
(86) PCT No.: PCT/CN2023/114268

§ 371 Date: Oct. 25, 2024

(30) Foreign Application Priority Data
Aug. 9, 2023 (CN) 202310998012.7

(51) Int. Cl. H10H 29/851; H10H 29/45; H10H 29/49; H10H 29/80; H10H 29/855

(52) U.S. Cl. CPC H10H 29/8514; H10H 29/45; H10H 29/49; H10H 29/8323; H10H 29/8512; H10H 29/8552

(57) ABSTRACT

The present disclosure provides a display panel and a display device. By providing a groove on at least a part of connection electrodes in the display panel, a first electrode is disposed in the groove. When micro light emitting diode devices emit light, the light will diffuse onto sidewalls and top surfaces of grooves disposed corresponding to the connection electrodes. This configuration allows the connection electrodes to reflect light emitted by the micro light emitting diode devices, thereby improving brightness of the display panel and reducing power consumption of the display panel.

### TECHNICAL FIELD

The present disclosure relates to the field of display technologies, and in particular to a display panel and a display device.

### BACKGROUND

Micro Light Emitting Diode (Micro-LED) display devices are widely used due to advantages such as high brightness, fast response speed, and long life, etc. The existing Micro-LED display devices include vertical Micro-LED display devices and flat Micro-LED display devices. Vertical Micro-LED display devices are particularly popular because its electrodes are located on two sides of light emitting materials. This configuration results in a smaller light-emitting chip area compared to flip-chip structured Micro-LED, eliminates the short-circuiting risk of P/N electrode(s), maximizes electrode area, provides symmetrical light distribution, and is easier to control in terms of light type compared to flip-chip structure Micro-LED, etc. However, during the use of vertical type Micro-LED display panel, it has been found that some light diffuses to the two sides, leading to light loss and higher power consumption.

Therefore, the existing Micro-LED display panel has a technical issue of light loss due to light diverging towards two sides.

### SUMMARY

An embodiment of the present disclosure provides a display panel and a display device for alleviating the technical issue of light loss due to light diverging towards two sides in the existing Micro-LED display devices.

In order to solve the above problems, the technical solutions provided by the embodiments of the present disclosure are as follows:

An embodiment of the present disclosure provides a display panel including:
a first substrate including a driving circuit layer and a connection electrode layer, wherein the connection electrode layer is disposed on one side of the driving circuit layer;
a second substrate disposed opposite to the first substrate, the second substrate including a transparent electrode layer; and
a plurality of micro light emitting diode devices disposed between the first substrate and the second substrate, each of the micro light emitting diode devices includes a first electrode, a second electrode, and a light-emitting layer, wherein the light-emitting layer is disposed between the first electrode and the second electrode;
wherein the connection electrode layer includes a plurality of connection electrodes, at least a part of the connection electrodes has a groove, the first electrode is disposed in the groove, the first electrode is connected to the connection electrode, and the second electrode is connected to the transparent electrode layer.

At the same time, embodiments of the present disclosure provide a display device, which includes the display panel as described in the above embodiment.

### BRIEF DESCRIPTION OF THE DRAWINGS

The technical solutions and other beneficial effects of the present disclosure will be apparent through a detailed description of the specific embodiments of the present disclosure in conjunction with the accompanying drawings.

FIG. 1 is a first schematic diagram of a display panel according to an embodiment of the present disclosure.

FIG. 2 is a second schematic diagram of a display panel according to an embodiment of the present disclosure.

FIG. 3 is a third schematic diagram of a display panel according to an embodiment of the present disclosure.

### DETAILED DESCRIPTION

The technical solutions in the embodiments of the present disclosure will be clearly and completely described below in conjunction with the accompanying drawings of the embodiments of the present disclosure. It should be appreciated that the described embodiments are merely some of the embodiments of the present disclosure, rather than all of the embodiments. Based on the embodiments in the present disclosure, all other embodiments obtained by a person of ordinary skill in the art without creative labor fall within the scope of the present disclosure.

In the description of the present disclosure, it should be understood that orientations or positional relationships indicated by terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, and others are based on the orientations or positional relationships shown in the accompanying drawings. They are used merely for the convenience of describing the present disclosure and simplifying the description, and are not intended to indicate or imply that the device or element indicated must have a specific orientation or be constructed and operated in a specific orientation. Therefore, they should not be construed as limitations on the present disclosure. Furthermore, the terms “first” and “second” are used solely for descriptive purposes and should not be interpreted as indicating relative importance or implicitly specifying the number of technical features. Thus, features designated with “first” or “second” may explicitly or implicitly include one or more of the described features. In the disclosure, the term “plurality” means two or more than two, unless explicitly defined otherwise.

In the description of the present disclosure, it should be noted that unless otherwise explicitly specified and defined, the terms “install”, “connect”, and “connection” should be interpreted broadly. For example, these terms can refer to fixed, detachable, or integrated connections; can refer to mechanical connections, electrical connections, or communication with each other; can refer to direct connections or indirect connections through an intermediary medium; and can refer to internal communication relationships within two components or interaction relationships between two components. For those skilled in the art, the specific meanings of these terms in the present disclosure can be understood based on the specific circumstances.

In this present disclosure, unless otherwise explicitly specified and limited, expressions of the first feature “above” or “below” the second feature may include a fact that the first and second features are in direct contact, and may also include a fact that the first and second features are not in direct contact but in contact through other features between them. Furthermore, expressions of the first feature “above”, “over”, and “on” the second feature include a fact that the first feature is directly above, diagonally above the second feature, or merely indicate that the first feature is at a higher horizontal level than the second feature. Expressions of the first feature “below”, “under”, and “beneath” the second feature include a fact that the first feature is directly below, diagonally below the second feature, or merely indicate that the first feature is at a lower horizontal level than the second feature.

The following disclosure provides various embodiments or examples to implement different structures of the present disclosure. To simplify the disclosure, certain components and configurations in particular examples are described below. These examples are provided solely for illustrative purposes and do not limit the scope of the disclosure. Additionally, reference numbers and/or signs may be repeated across different examples for simplicity and clarity, and such repetition does not imply any relationship between the discussed embodiments and/or configurations. Furthermore, while the disclosure provides certain examples of processes and materials, a person skilled in the art will recognize the applicability of other processes and/or the use of other materials.

Embodiments of the present disclosure provide a display panel and a display device for alleviating the above technical problem of light loss due to light dispersion to two sides of the existing Micro-LED display device.

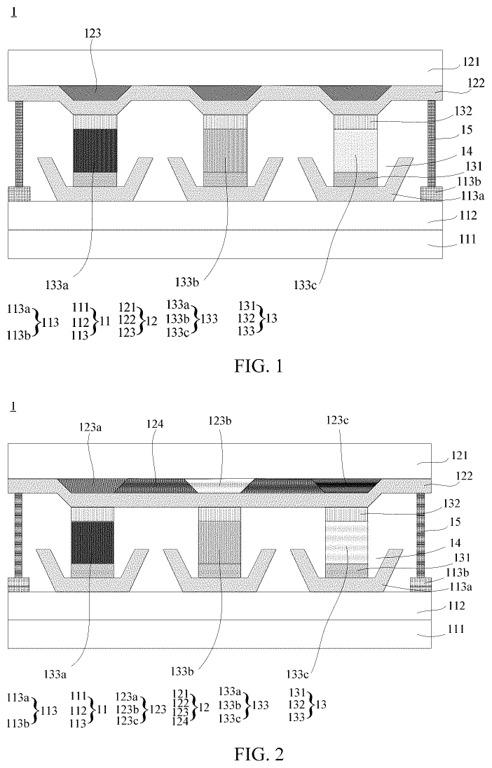

As shown in FIG. 1, an embodiment of the present disclosure provides a display panel. The display panel 1 includes:
a first substrate 11 including a driving circuit layer 112 and a connection electrode layer 113, wherein the connection electrode layer 113 is disposed on one side of the driving circuit layer 112;
a second substrate 12 disposed opposite to the first substrate 11, the second substrate 12 including a transparent electrode layer 122; and
a plurality of micro light emitting diode devices 13 disposed between the first substrate 11 and the second substrate 12, each of the micro light emitting diode devices 13 includes a first electrode 131, a second electrode 132 and a light-emitting layer 133, where the light-emitting layer 133 is disposed between the first electrode 131 and the second electrode 132.

Herein, the connection electrode layer 113 includes a plurality of connection electrodes 113a. At least a part of the connection electrodes 113a have a groove 14. The first electrode 131 is disposed in the groove 14. The first electrode 131 is connected to the connection electrodes 113a. The second electrode 132 is connected to the transparent electrode layer 122.

This embodiment of the present disclosure provides a display panel. The display panel includes grooves on at least a part of the connection electrodes, with the first electrode positioned within the grooves. When the micro light emitting diode devices emit light, the light will diffuse onto sidewalls and the top surfaces of the grooves corresponding to the connection electrodes. This configuration allows the connection electrodes to reflect the light emitted by the micro light emitting diode devices, thereby increasing utilization of the emitted light, avoiding light loss, improving brightness of the display panel, and reducing power consumption of the display panel.

To address an issue of poor contact between the micro light emitting diode devices and the transparent electrode layer caused by potential height differences among various micro light emitting diode devices, in some embodiments, as shown in FIG. 1, the second substrate 12 further includes support pads 123. The support pads 123 are disposed on a side of the transparent electrode layer 122 away from the micro light emitting diode devices 13. The support pads 123 are disposed corresponding to the second electrode 132. By disposing the support pads on the second substrate on the side of the transparent electrode layer away from the micro light emitting diode devices and corresponding to the second electrode, the transparent electrode layer can be supported by the support pads, even if there are height differences among different micro light emitting diode devices during aligning the second substrate with the first substrate, which result in gaps between the micro light emitting diode devices and the transparent electrode layers, the height differences are reduced, so that the transparent electrode layer is in contact with the second electrodes of the micro light emitting diode devices. This improves contact impedances between the transparent electrode layer and the second electrodes of the micro light emitting diode devices, thereby improving yield of the display panel.

Specifically, micro light emitting diode devices with different light emitting colors are considered as having different thicknesses. For example, light emitting efficiencies of the micro light emitting diode devices with different light emitting colors are different, and thicknesses of light emitting materials of the micro light emitting diode devices with different light emitting colors are different, which leads to height differences among different micro light emitting diode devices, and in turn leads to a poor contact effect between the transparent electrode layer and the second electrodes. In the embodiments of the present disclosure, a support pad is disposed corresponding to the second electrode, so that the transparent electrode layer can be supported by support pads. The transparent electrode layer can be in contact with the second electrodes, thereby improving contact effects between the transparent electrode layer and the second electrodes. Also due to a certain elasticity of the support pads, the micro light emitting diode devices will not be damaged under squeezing.

Specifically, a width of the support pad is greater than a width of the second electrodes. When the width of the support pad is greater than the width of the second electrode, the contact effect between the transparent electrode layer and the second electrode is relatively good. The alignment connection between the support pads and the second electrode is facilitated. The process difficulty is reduced. The yield rate of the display panel is improved.

In some embodiments, a material of the support pads includes organic photoresist material. By organic photoresist material included in the support pads, the support pads have good elasticity. When the transparent electrode layer is supported by the support pads, the part of transparent electrode layer disposed corresponding to the micro light emitting diode devices with relatively small thickness can be directly contacted with the second electrode. A support pad disposed corresponding to the micro light emitting diode devices with relatively great thickness can be compressed and contracted, thereby avoiding damage of the micro light emitting diode devices caused by squeezing the micro light emitting diode devices.

Specifically, an elastic modulus of the support pad is smaller than an elastic modulus of the transparent electrode layer. Through better elasticity of the support pad than that of the transparent electrode layer, the support pad can support the transparent electrode layer, thereby improving the contact effect between the transparent electrode layer and the second electrodes.

Specifically, the micro light emitting diode devices exemplarily include red micro light emitting diode devices, blue micro light emitting diode devices, and green micro light emitting diode devices. For example, a thickness of the blue micro light emitting diode devices is greater than a thickness of the red micro light emitting diode devices. When the support pads support the transparent electrode layer, the support pads press the transparent electrode layer downward in the area corresponding to the red micro light emitting diode devices. The part of the transparent electrode layer corresponding to the red micro light emitting diode devices can properly contact with the second electrode. The support pads can be compressed and contracted in the area corresponding to the blue micro light emitting diode devices, so as to avoid damage caused by squeezing the blue micro light emitting diode devices, thereby improving the yield of the display panel.

Specifically, support pads corresponding to the micro light emitting diode devices having different light emitting colors have different thicknesses, so that the support pads can solve the problem of poor contact effect with the transparent electrode layer caused by height differences among different micro light emitting diode devices, which also can prevent the micro light emitting diode devices from being damaged by squeezing, thereby improving the yield of the display panel.

Specifically, a material of the support pads includes a transparent material. By providing a transparent material for the support pads, the support pads can be prevented from blocking light and causing light loss.

In some embodiments, as shown in FIG. 2, the support pads 123 includes a first color conversion section 123a, a second color conversion section 123b, and a third color conversion section 123c. The first color conversion section 123a, the second color conversion section 123b, and the third color conversion section 123c are disposed corresponding to the micro light emitting diode devices 13, respectively. In such case, it can improve color purity of the micro light emitting diode devices and improve display effect of the display panel.

Specifically, a material of the support pads includes quantum dots. The quantum dots include red light quantum dots, green light quantum dots, and blue light quantum dots. The red light quantum dots, the green light quantum dots, and the blue light quantum dots are disposed corresponding to the micro light emitting diode devices respectively. In such case, it can improve color purity of the micro light emitting diode devices and improve display effect of the display panel.

Accordingly, a material of the first color conversion section is the red light quantum dots, a material of the second color conversion section is the green light quantum dots, and a material of the third color conversion section is the blue light quantum dots.

Specifically, the shape of the quantum dots includes spherical, cuboidal, prismatic, and other shapes. A material of the quantum dots includes hydrogel-loaded quantum dot structure, QD@MOFs, CdSeSiO2, II-VIA, III-VA QD-Nanorod, Dot-in-rod QD core-shell structure Nanorod, double-emitting, triple-emitting quantum dot materials, and perovskite quantum dots. The red light quantum dots, the green light quantum dots, and the blue light quantum dots all include a luminescent core and an inorganic protective shell. A material of the luminescent core of the green light quantum dots includes ZnCdSe2, InP, Cd2SSe, and other materials. A material of the luminescent core of the red light quantum dots includes CdSe, Cd2SeTe, InAs, and other materials. Materials of the inorganic protective shells of both the red light quantum dots and the green light quantum dots include CdS, ZnSe, ZnCdS2, ZnS, ZnO, and other materials. The blue light quantum dots are blue light quantum dots of CdSe@ZnS in a core-shell structure and blue light quantum dots of ZnCdS@ZnS in a core-shell structure. Herein, “CdSe@ZnS” means CdSe coated with ZnS, and “ZnCdS@ZnS” means ZnCdS coated with ZnS.

In some embodiments, a material of the support pad includes an organic photoresist material, which consists of a red color resist, a green color resist, and a blue color resist. Each of the red color resist, the green color resist, and the blue color resist is disposed corresponding to the micro light emitting diode devices respectively. In such case, color purity of the micro light emitting diode devices can be improved, thereby improving the display performance of the display panel.

Accordingly, a material of the first color conversion section is a red color resist, a material of the second color conversion section is a green color resist, and a material of the third color conversion section is a blue color resist.

In some embodiments, as shown in FIG. 2, the second substrate 12 further includes a light-shielding layer 124, which is disposed between adjacent support pads 123. In such case, it can reduce reflection on wires on the first substrate, and avoid interference caused by light reflecting from the wires on the first substrate. Additionally, it can prevent external light from illustrating onto the display panel and causing reflection, thus enhancing the display panel's display performance.

Specifically, a material of the light-shielding layer includes black color resist and black oxide.

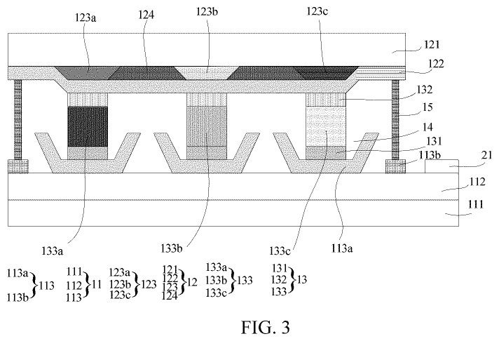

In some embodiments, as shown in FIG. 3, the display panel 1 further includes a conductive electrode 15 and a driving chip 21. The connection electrode layer 113 further includes commonly communicating electrodes 113b. The conductive electrode 15 connects the transparent electrode layer 122 and the commonly communicating electrodes 113b. The conductive electrode 15 is connected to the driving chip 21. By providing the conductive electrode, the connection electrode layer includes the commonly communicating electrode. The conductive electrode is connected to the transparent electrode layer and the commonly communicating electrodes. The conductive electrode can input a signal to the transparent electrode layer through the commonly communicating electrodes, so that the transparent electrode layer works properly.

Specifically, the conductive electrode includes either a conductive Au ball or a conductive silver paste.

In some embodiments, a depth of the groove is greater than a thickness of the first electrode. This configuration allows at least a part of the light-emitting layer of the micro light emitting diode devices to be disposed in the groove. When the micro light emitting diode devices emit light, the emitted light can illuminate sidewalls and top surface of the connection electrodes. Thereby, it can improve the light reflection effect of the micro light emitting diode devices, further reduce light loss, improve light utilization rate of the display panel, and reduce power consumption of the display panel.

Specifically, the depth of the groove can be one third to one half of the thickness of the micro light emitting diode devices.

In some embodiments, the first electrode is in contact with top surfaces of the connection electrodes and lateral surfaces of the connection electrodes. In such case, it can improve the contact effect between the first electrode and the connection electrodes, reduce contact resistance between them, and decrease power consumption of the display panel.

In some embodiments, the display panel further includes filling adhesive, and the filling adhesive is disposed between adjacent micro light emitting diode devices.

In some embodiments, the micro light emitting diode devices include red micro light emitting diode devices, green micro light emitting diode devices, and blue micro light emitting diode devices. As shown in FIG. 1, the light-emitting layer 133 includes a red light-emitting layer 133a, a green light-emitting layer 133b, and a blue light-emitting layer 133c.

In some embodiments, as shown in FIG. 1, the first substrate 11 further includes a first substrate 111, a material of which includes glass and polyimide.

In some embodiments, as shown in FIG. 1, the second substrate 12 further includes a second substrate 121, a material of which includes glass and polyimide.

In some embodiments, the light-emitting layer includes a quantum well layer.

In some embodiments, a material of the connection electrode layer includes silver.

At the same time, an embodiment of the present disclosure provides a display panel manufacturing method, which involves a display panel as described in any of the above embodiments.

Specifically, the display panel manufacturing method includes:
forming a driving circuit layer and a connection electrode layer on a first substrate through processes such as film formation, exposure, development, and etching, etc.;
etching the connection electrode layer to create a groove;
soldering first electrodes of a plurality of micro light emitting diode devices onto connection electrodes on the first substrate through a massive transfer process and a bonding process;
depositing a transparent conductive layer on a second substrate; and
aligning the first substrate, to which the micro light emitting diode devices are bonded, with the second substrate under vacuum, so as to contact second electrodes of the micro light emitting diode devices with the transparent conductive layer, wherein a plurality of the micro light emitting diode devices are disposed corresponding to a red color resist, a green color resist, and a blue color resist, respectively.

In some embodiments, before depositing the transparent conductive layer on the second substrate, the method further includes:
preparing support pads on the second substrate through processes of photoresist coating, exposure, development, baking, etc. The support pads are disposed corresponding to second electrodes of the micro light emitting diode devices.

In some embodiments, before depositing the transparent conductive layer on the second substrate, the method further includes:
forming a light-shielding layer on the second substrate through processes of photoresist coating, exposure, development, baking, etc. ;
preparing the red color resist through processes of photoresist coating, exposure, development, baking, etc. ;
preparing the green color resist using processes of photoresist coating, exposure, development, baking, etc. ; and
preparing the blue color resist using processes of photoresist coating, exposure, development, baking, etc.

The above embodiments respectively describe a structure of a display panel from the perspective of various film layers and the combination of these film layers. When there is no conflict between various embodiments, they can be combined to achieve better technical effects, which will not be described again here. For example, the support pads include a red color resist, a green color resist, and a blue color resist. The red color resist, the green color resist, and the blue color resist are disposed corresponding to the micro light emitting diode devices respectively, and the depth of the grooves is greater than the thickness of the first electrodes.

At the same time, an embodiment of the present disclosure provides a display device, which includes a display panel as described in any of the above embodiments.

Specifically, the display device further includes a flexible printed circuit.

According to the above embodiments, it can be known that:

Embodiments of the present disclosure provide a display panel and a display device. The display panel includes a first substrate, a second substrate and a plurality of micro light emitting diode devices. The first substrate includes a driving circuit layer and a connection electrode layer. The connection electrode layer is disposed on one side of the driving circuit layer. The second substrate is disposed opposite to the first substrate. The second substrate includes a transparent electrode layer. The plurality of micro light emitting diode devices are disposed between the first substrate and the second substrate. Each of the micro light emitting diode devices includes a first electrode, a second electrode, and a light-emitting layer. The light-emitting layer is disposed between the first electrode and the second electrode. Herein, the connection electrode layer includes a plurality of connection electrodes. At least a part of the connection electrodes has a groove. The first electrode is disposed in the groove. The first electrode is connected to the connection electrode. The second electrode is connected to the transparent electrode layer. By providing grooves on at least a part of the connection electrodes and disposing the first electrode in the groove, light will diffuse onto sidewalls and the top surfaces of the grooves corresponding to the connection electrodes when the micro light emitting diode devices emit light. This configuration allows the connection electrodes to reflect the light emitted by the micro light emitting diode devices, thereby increasing utilization of the emitted light, avoiding light loss, improving brightness of the display panel, and reducing power consumption of the display panel.

In the above embodiments, each embodiment focuses on different perspectives. Parts that are not described in detail in a certain embodiment can refer to relevant descriptions in other embodiments.

The above is a detailed introduction to a display panel and a display device provided by the embodiments of the present disclosure. Specific examples are used herein to illustrate the principles and implementations of the present disclosure. The description of the above embodiments is only used to help understand the technical solution and the core idea of the present disclosure. Those of ordinary skill in the art should understand that they can still modify the technical solutions recorded in the foregoing embodiments, or make equivalent substitutions for some of the technical features. And these modifications or substitutions do not make the essence of the corresponding technical solutions deviate from the scope of the technical solutions of the embodiments of the present disclosure.

1. A display panel, comprising:
a first substrate comprising a driving circuit layer and a connection electrode layer, wherein the connection electrode layer is disposed on one side of the driving circuit layer;
a second substrate disposed opposite to the first substrate, the second substrate comprising a transparent electrode layer; and
a plurality of micro light emitting diode devices disposed between the first substrate and the second substrate, each of the micro light emitting diode devices comprising a first electrode, a second electrode, and a light-emitting layer, wherein the light-emitting layer is disposed between the first electrode and the second electrode;
wherein the connection electrode layer comprises a plurality of connection electrodes, at least a part of the connection electrodes has a groove, the first electrode is disposed in the groove, the first electrode is connected to the connection electrode, and the second electrode is connected to the transparent electrode layer.

2. The display panel of claim 1, wherein the second substrate further comprises support pads, the support pads are disposed on a side of the transparent electrode layer away from the micro light emitting diode devices, the support pads are disposed corresponding to the second electrode, and a width of the support pad is greater than a width of the second electrode.

3. The display panel of claim 2, wherein a material of the support pads comprises an organic photoresist material.

4. The display panel of claim 2, wherein the support pads comprise a first color conversion section, a second color conversion section, and a third color conversion section, wherein the first color conversion section, the second color conversion section, and the third color conversion section are disposed corresponding to the micro light emitting diode devices, respectively.

5. The display panel of claim 4, wherein of the support pads comprises either color photoresist or quantum dots.

6. The display panel of claim 5, wherein the second substrate further comprises a light-shielding layer, and the light-shielding layer is disposed between adjacent support pads.

7. The display panel of claim 1, wherein the display panel further comprises a conductive electrode and a driving chip, the connection electrode layer further comprises a commonly communicating electrode, the conductive electrode connects the transparent electrode layer and the commonly communicating electrode, and the conductive electrode is connected to the driving chip.

8. The display panel of claim 1, wherein a depth of the groove is greater than a thickness of the first electrode.

9. The display panel of claim 8, wherein the conductive electrode comprises either a conductive Au ball or a conductive silver paste.

10. The display panel of claim 1, wherein the first electrode is in contact with top surfaces of the connection electrodes and lateral surfaces of the connection electrodes.

11. A display device comprising a display panel, wherein the display panel comprises:
a first substrate comprises a driving circuit layer and a connection electrode layer, wherein the connection electrode layer is disposed on one side of the driving circuit layer;
a second substrate disposed opposite to the first substrate, the second substrate comprising a transparent electrode layer; and
a plurality of micro light emitting diode devices disposed between the first substrate and the second substrate, each of the micro light emitting diode devices comprising a first electrode, a second electrode, and a light-emitting layer, wherein the light-emitting layer is disposed between the first electrode and the second electrode;
wherein the connection electrode layer comprises a plurality of connection electrodes, at least a part of the connection electrodes has a groove, the first electrode is disposed in the groove, the first electrode is connected to the connection electrode, and the second electrode is connected to the transparent electrode layer.

12. The display device of claim 11, wherein the second substrate further comprises support pads, the support pads are disposed on a side of the transparent electrode layer away from the micro light emitting diode devices, the support pads are disposed corresponding to the second electrode, and a width of the support pad is greater than a width of the second electrode.

13. The display device of claim 12, wherein a material of the support pads comprises an organic photoresist material.

14. The display device of claim 12, wherein the support pads comprise a first color conversion section, a second color conversion section, and a third color conversion section, wherein the first color conversion section, the second color conversion section, and the third color conversion section are disposed corresponding to the micro light emitting diode devices, respectively.

15. The display device of claim 14, wherein a the support pads comprises either color photoresist or quantum dots.

16. The display device of claim 15, wherein the second substrate further comprises a light-shielding layer, and the light-shielding layer is disposed between adjacent support pads.

17. The display device of claim 11, wherein the display panel further comprises a conductive electrode and a driving chip, the connection electrode layer further comprises a commonly communicating electrode, the conductive electrode connects the transparent electrode layer and the commonly communicating electrode, and the conductive electrode is connected to the driving chip.

18. The display device of claim 11, wherein a depth of the groove is greater than a thickness of the first electrode.

19. The display device of claim 18, wherein the conductive electrode comprises either a conductive Au ball or a conductive silver paste.

20. The display device of claim 11, wherein the first electrode is in contact with top surfaces of the connection electrodes and lateral surfaces of the connection electrodes.
